(19) United States
(12) Patent Application Publication
(10) Pub. No.: US 2011/0016888 A1
(43) Pub. Date: Jan. 27, 2011

(54) THERMOELECTRIC MODULE

(75) Inventors: Frank Haaß, Erzhausen (DE); Madalina Andreea Stefan, Ludwigshafen (DE); Georg Degen, Lorsch (DE)

Correspondence Address: CONNOLLY BOVE LODGE & HUTZ, LLP, P O BOX 2207, WILMINGTON, DE, 19899, US

(73) Assignee: BASF SE, Ludwigshafen (DE)

(21) Appl. No.: 12/840,684

(22) Filed: Jul. 21, 2010

(30) Foreign Application Priority Data
Jul. 24, 2009 (EP) 09166365.8

(51) Int. Cl. F25B 21/02; H01L 35/02; H01L 35/30; F16L 55/00

(52) U.S. Cl. 62/3.3; 136/200; 136/222; 138/103

(57) ABSTRACT

The thermoelectric module composed of p- and n-conducting thermoelectric material legs which are mutually connected to one another via electrically conductive contacts, is characterized by the fact that the electrically conductive contacts have on the cold and hot sides of the thermoelectric module between the thermoelectric material legs in their course at least one flexibility location which permits flexure and slight displacement of the thermoelectric material legs relative to one another.

The invention relates to thermoelectric modules suitable for application to non-planar, solid heat transfer medium surfaces.

Thermoelectric generators and Peltier arrangements as such have been known for a long time. p- and n-doped semiconductors which are heated on one side and cooled on the other side transport electrical charges through an external electric circuit, and electrical work can be performed at a load in the electric circuit. The efficiency of the conversion of heat into electrical energy that is achieved in the process is limited thermodynamically by the Carnot efficiency. Thus, at a temperature of 1000 K on the hot side and 400 K on the “cold” side, an efficiency of (1000-400): 1000=60% would be possible. However, only efficiencies of up to 6% have been achieved to date.

On the other hand, if a direct current is applied to such an arrangement, then heat is transported from one side to the other side. Such a Peltier arrangement works as a heat pump and is therefore suitable for cooling apparatus parts, vehicles or buildings. Heating via the Peltier principle is also more favorable than conventional heating because more heat is always transported than corresponds to the energy equivalent supplied.

At present, thermoelectric generators are used in space probes for generating direct currents, for cathodic corrosion protection of pipelines, for energy supply to light buoys and radio buoys, and for operating radios and television sets. The advantages of thermoelectric generators reside in their extreme reliability. For instance, they work independently of atmospheric conditions such as air humidity; there is no disturbance-prone mass transfer, but rather only charge transfer; the fuel is combusted continuously, including catalytically without a free flame, as a result of which only small amounts of CO, NOₓ and uncombusted fuel are released; it is possible to use any fuels from hydrogen through natural gas, gasoline, kerosene, diesel fuel up to biologically obtained fuels such as rapeseed oil methyl ester.

Thermoelectric energy conversion thus fits extremely flexibly into future requirements such as hydrogen economy or energy generation from renewable energies.

### BRIEF DESCRIPTION OF THE DRAWINGS

FIG. 1, schematically illustrates a contact connection for a thermoelectric module.

FIG. 2, illustrates a thermoelectric module.

FIG. 3, schematically illustrates a thermoelectric module on an oval heat transfer medium pipe.

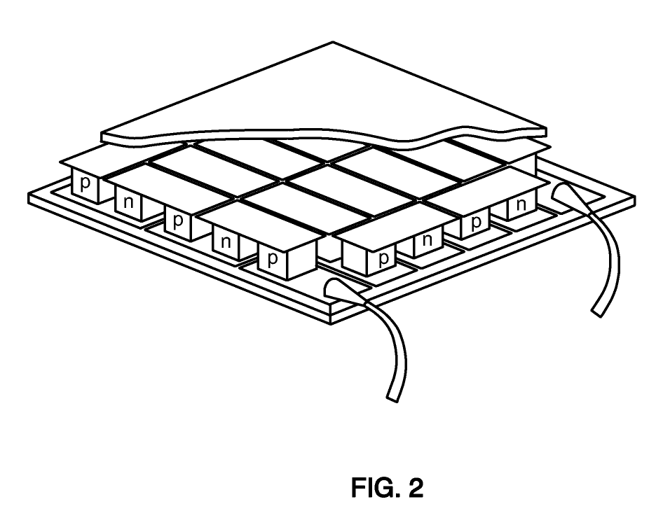

A thermoelectric module consists of p- and n-legs, which are connected electrically in series and thermally in parallel. FIG. 2 shows such a module.

The traditional construction consists of two ceramic plates, between which the individual legs are applied in alternation. Electrically conductive contact is made with every two legs via the end faces.

In addition to the electrically conductive contact-connection, different further layers are normally also applied on the actual material, which serve as protective layers or as solder layers. Ultimately, the electrical contact between two legs is established, however, via a metal bridge.

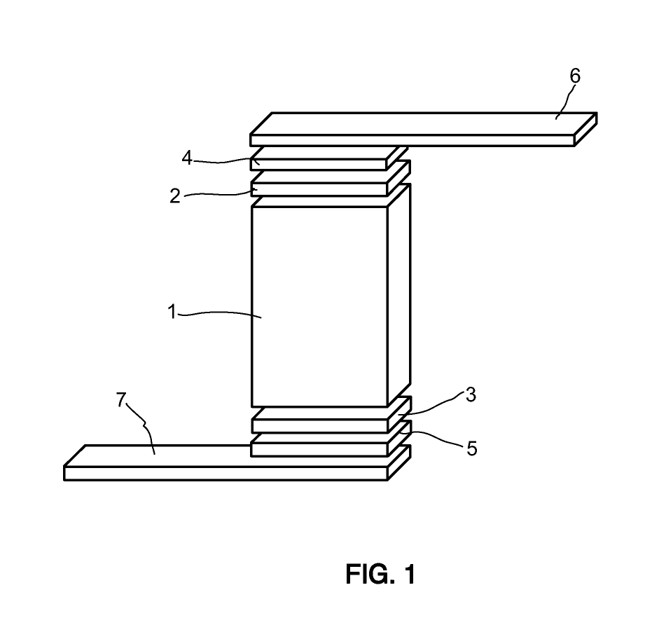

An essential element of thermoelectric components is the contact-connection. The contact-connection establishes the physical connection between the material in the “heart” of the component (which is responsible for the desired thermoelectric effect of the component) and the “outside world”. In detail, the construction of such a contact is illustrated schematically in FIG. 1.

The thermoelectric material 1 within the component provides for the actual effect of the component. This is a thermoelectric leg. An electric current and a thermal current flow through the material 1 in order that the latter fulfils its purpose in the overall construction.

The material 1 is connected to the supply lines 6 and 7 via the contacts 4 and 5, respectively, on at least two sides. In this case, the layers 2 and 3 are intended to symbolize one or more intermediate layers which may be necessary (barrier material, solder, adhesion promoter or the like) between the material 1 and the contacts 4 and 5. The segments 2/3, 4/5, 6/7 respectively associated with one another in pairs can, but need not, be identical. This ultimately likewise depends on the specific construction and the application, just like the flow direction of electric current and thermal current through the construction.

An important role is accorded, then, to the contacts 4 and 5. The latter provide for a close connection between material and supply line. If the contacts are poor, then high losses occur here, which can severely restrict the performance of the component. For this reason, the legs and contacts in the application are frequently also pressed onto the material. The contacts are thus subjected to high mechanical loading. This mechanical loading also increases as soon as elevated (or else reduced) temperatures or/and thermal cycling play a part. The thermal expansion of the materials incorporated in the component leads inevitably to mechanical stress, which leads in the extreme case to failure of the component as a result of detachment of the contact.

In order to prevent this, the contacts used must have a certain flexibility and spring properties in order that such thermal stresses can be compensated for.

In order to impart stability to the whole structure and to ensure the necessary, substantially homogeneous thermal coupling over the total number of legs, carrier plates are required. For this purpose, a ceramic is usually used, for example composed of oxides or nitrides such as Al₂O₃, SiO₂ or AlN.

This typical construction entails a series of disadvantages. The ceramic and the contacts can be mechanically loaded only to a limited extent. Mechanical and/or thermal stresses can easily lead to cracks or detachment of the contact-connection, rendering the entire module unusable.

Furthermore, limits are also imposed on the traditional construction with regard to application, since only planar surfaces can ever be connected to the thermoelectric module. A close connection between the module surface and the heat source/heat sink is indispensable in order to ensure sufficient heat flow.

Non-planar surfaces, such as a round waste heat pipe, for example, are not amenable to direct contact with the traditional module, or require a corresponding straightened heat exchanger construction in order to provide a transition from the non-planar surface to the planar module.

The contact-connection in the thermoelectric modules is generally rigid. Lead telluride application concepts are described in Mat. Res. Soc. Symp. Proc. Vol. 234, 1991, pages 167 to 177. FIG. 1 shows a contact-connection in which, on the cold side of the thermoelectric module, the contact exhibits a U-shaped protuberance. On the hot side of the module, contact-connection is effected by rigid contacts. This type of contact-connection also does not permit use on non-planar surfaces.

It is an object of the present invention to provide thermoelectric modules which can be adapted flexibly to non-planar heat transfer medium surfaces and react flexibly to thermal and mechanical loading.

The object is achieved according to the invention by means of a thermoelectric module composed of p- and n-conducting thermoelectric material legs which are mutually connected to one another via electrically conductive contacts, wherein the electrically conductive contacts have on the cold and hot sides of the thermoelectric module between the thermoelectric material legs in their course at least one flexibility location which permits flexure and slight displacement of the thermoelectric material legs relative to one another.

The expression “flexibility location” describes a location in the course of the electrical contact which allows flexure or displacement of the contact connected to the p-leg and n-leg. The two material legs are intended to be slightly displaceable relative to one another. In this case, the term “slightly” describes a displacement by a maximum of 20%, particularly preferably a maximum of 10%, of the distance between the respective p- and n-conducting, thermoelectric material legs. The possibility of flexure ensures that the contact-connection of none of the material legs is detached if the thermoelectric module is adapted to a non-planar surface.

Flexure is intended to be possible preferably by an angle of a maximum of 45°, particularly preferably a maximum of 20°, without the contact-connection of the thermoelectric material legs being detached.

The flexibility location can have any desired suitable form, provided that the function described above is fulfilled. The flexibility location is preferably present in the form of at least one U-shaped, V-shaped or rectangular protuberance of the respective contact. Particularly preferably, a U-shaped, V-shaped or rectangular protuberance of the respective contract is present.

Alternatively, the flexibility location may preferably be present in the form of an undulation, spiral or in sawtooth form of the respective contact.

The thermoelectric module according to the invention is advantageous particularly when the thermoelectric material legs are arranged in non-planar fashion. This means that the thermoelectric material legs are not arranged parallel to a plane.

The design according to the invention of the thermoelectric material legs allows the spiral winding of the thermoelectric module onto a pipe of any desired cross section. Rectangular, round, oval or other cross sections can be involved in this case.

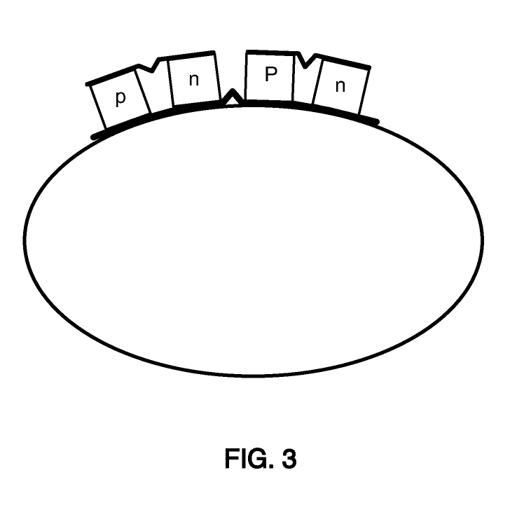

FIG. 3 shows, in a basic schematic diagram, how the thermoelectric module can be wound around an oval heat transfer medium pipe.

The adaptation of the thermoelectric module to any desired three-dimensional surfaces of the heat exchange material is thus possible according to the invention. In this way, even non-planar heat sources or heat sinks are amenable to a close connection to the thermoelectric module.

Waste heat or coolants are typically conducted through a pipe. An automobile exhaust gas pipe is particularly preferably involved.

The design according to the invention of the flexibility and displaceability of the contacts permits better compensation and reduction of thermal and mechanical stresses.

By virtue of the windability of the thermoelectric modules, a strand of alternating p- and n-legs can be wound around a round or oval pipe without detachment of the contacts. This permits cost-effective, rapid and simple integration of thermoelectric components for example into the exhaust gas section of an automobile in, around, on, before or after a motor vehicle catalytic converter, in a heating device, etc.

The electrically conductive contacts can be constructed from any suitable materials. They are typically constructed from metals or metal alloys, for example iron, nickel, aluminum, platinum or other metals. It is necessary to ensure a sufficient thermal stability of the metal contact-connection since the thermoelectric modules are often exposed to high temperatures.

According to one embodiment of the invention the electrically conductive contacts are prepared from at least one ductile metal, connected with at least one harder metal. The ductile metal has a lower hardness than the harder metal. Examples of the ductile metals are copper and aluminum. Examples for harder metals are iron, steel or nickel. If the more ductile metal and the harder metal or material are layered, a flexibility location in the electrode is created. Preferably, the layer of the ductile metal is thicker than the layer of the less ductile material.

According to one embodiment of the invention the electrically conductive contacts are prepared by layered manufacturing or metal injection molding (MIM).

The layered manufacturing is preferably a selective laser sintering (SLS) or selective laser melting (SLM).

Layered manufacturing (LM) processes which can be employed are described in Annals of the CIRP Vol. 56/2/2007, pages 730 to 759. The preparation process is preferably rapid manufacturing (RM) or rapid prototyping (RP). Among the layered manufacturing (LM) techniques are the photo-polymerization (stereolithography SLA), the ink-jet-printing (IJP), the 3D-printing (3DP), the fused deposition modeling (FDM), the selective laser sintering (SLS) and selective laser melting (SLM), as well as the selective electron-beam-melting (EBM). Also laminated object manufacturing (LOM), laser cladding (LC) can be employed. These processes are exemplified in the above literature section.

The mechanical strength can be increased further by embedding the thermoelectric material legs into a solid matrix material that is not electrically conductive.

In order that the thermoelectric material is kept stable in a wrapped form, it is recommendable to use a matrix or a grid to stabilize the thermoelectric module. For this purpose, materials having low thermal conductivity and no electrical conductivity are preferably used. Examples of suitable materials are aerogels, ceramics, particularly foamed ceramics, glass wool, glass ceramic mixtures, electrically insulated metal grids, mica or a combination of these materials. For the temperature range up to 400° C., it is also possible to use synthetic carbon-based polymers such as polyurethanes, polystyrene, polycarbonate, polypropylene, or naturally occurring polymers such as rubber. The matrix materials can be used as a powder, as a shaped body, as a suspension, as a paste, as a foam or as a glass. The matrix can be cured by heat treatment or irradiation, and also by evaporation of the solvents or by crosslinking of the materials used. The matrix can already be adapted to the corresponding application by shaping before use, or be cast, injected, sprayed, knife-coated or applied during the application.

The electrical contacts can be connected to the thermoelectric material legs in any desired manner. By way of example, they can be applied to the legs beforehand, for example by placement, pressing, soldering, welding, prior to incorporation into a thermoelectric module, and they can also be applied to the electrically insulating substrate. In addition, it is possible to press, solder or weld them together with the electrically insulated substrates and the thermoelectric legs in a single-step method.

The thermoelectric modules can be contacted with the heat transfer medium in any suitable manner. The thermoelectric module can be wound for example externally, i.e. around a pipe, and internally, i.e. on an inner carrier fitted in the pipe. The inner carrier can be an electrically insulating coating or layer on the inner wall of the pipe. As a result of being fitted to the inner carrier, the thermoelectric material/leg can be directly contacted with the heat transfer medium.

Typically, either heat transfer media for cooling purposes are contacted, or heated exhaust gases from heating systems or from internal combustion engines. However, it is also possible to place the thermoelectric modules for waste heat utilization onto the non-reflectively coated side of the parabolic troughs in photovoltaics on melting boiler walls or reactor walls.

The invention correspondingly also relates to the use of the thermoelectric modules for application to non-planar, solid heat transfer medium surfaces and exhaust gas lines with thermoelectric modules as described above wound spirally thereon.

The semiconductor materials according to the invention can also be joined together to form thermoelectric generators or Peltier arrangements according to methods which are known per se to the person skilled in the art and are described for example in WO 98/44562, U.S. Pat. No. 5,448,109, EP-A-1 102 334 or U.S. Pat. No. 5,439,528.

The thermoelectric generators or Peltier arrangements according to the invention generally widen the available range of thermoelectric generators and Peltier arrangements. By varying the chemical composition of the thermoelectric generators or Peltier arrangements, it is possible to provide different systems which satisfy different requirements in a multiplicity of possible applications. By way of example, different thermoelectric materials can be wound spirally around pipes, for example, which have different temperature ranges. ZT values can be adapted to these temperatures.

The present invention also relates to the use of a thermoelectric generator according to the invention or of a Peltier arrangement according to the invention
as a heat pump
for climate control of seating furniture, vehicles and buildings
in refrigerators and (laundry) driers
for simultaneous heating and cooling of substance streams in processes for substance separation such as
   absorption
   drying
   crystallization
   evaporation
   distillation
as a generator for utilization of heat sources such as
   solar energy
   geothermal heat
   heat of combustion of fossil fuels
   waste heat sources in vehicles and stationary units
   heat sinks in the evaporation of liquid substances
   biological heat sources
for cooling electronic components.

Furthermore, the present invention relates to a heat pump, a refrigerator, a (laundry) drier or a generator for utilizing heat sources, comprising at least one thermoelectric generator according to the invention or one Peltier arrangement according to the invention, by means of which, in the case of the (laundry) drier, a material to be dried is heated directly or indirectly and by means of which the water or solvent vapor obtained during drying is cooled directly or indirectly.

The invention is further illustrated by the following examples.

### EXAMPLES

### Example 1

In a prefabricated matrix (leg-holder) n- and p-legs made from PbTe are inserted. Fe-alloy electrodes having a thickness of approximately 1.5 mm were prepared using the rapid-prototyping-process. The electrodes were soldered, wherein improved contact was achieved by small amounts of PbTe-powder between the electrodes and the thermoelectric legs. The contact resistance was generally lower than the contact resistance of the contacts having flat electrodes.

### Example 2

n- and p-legs from PbTe-material were contacted with electrodes by hot pressing. The electrodes were prepared by MIM from a Fe-alloy, having a thickness of 2 mm.

The contacted legs were subsequently included in a metal capsule which was electrically insulated at the inside.

1. A thermoelectric module comprising: p- and n-conducting thermoelectric material legs which are mutually connected to one another via electrically conductive contacts, wherein the electrically conductive contacts have on cold and hot sides of the thermoelectric module between the thermoelectric material legs in their course at least one flexibility location which permits flexure and slight displacement of the thermoelectric material legs relative to one another.

2. The thermoelectric module according to claim 1, wherein the flexibility location is present in the form of at least one U-shaped, V-shaped or rectangular protuberance of the respective contact.

3. The thermoelectric module according to claim 1, wherein the flexibility location is present in the form of an undulation, spiral or in sawtooth form of the respective contact.

4. The thermoelectric module according to claim 1, wherein the electrically conductive contacts are prepared by layered manufacturing or metal injection molding (MIM).

5. The thermoelectric module according to claim 4, wherein the layered manufacturing is a selective laser sintering (SLS) or selective laser melting (SLM).

6. The thermoelectric module according to claim 1, wherein the electrically conductive contacts are prepared from at least one ductile metal, combined with at least one harder metal.

7. The thermoelectric module according to claim 1, wherein the thermoelectric material legs are arranged in non-planar fashion.

8. The thermoelectric module according to claim 7, wherein the thermoelectric material legs are wound spirally onto a pipe of any desired cross section.

9. The thermoelectric module according to claim 8, wherein waste heat or coolants are conducted through the pipe.

10. The thermoelectric module according to claim 9, wherein automobile exhaust gases are conducted through the pipe.

11. The thermoelectric module according to claim 1, wherein the thermoelectric material legs are embedded into a solid matrix material that is not electrically conductive.

12. An automobile exhaust gas line comprising the thermoelectric module as claimed in claim 1 wound spirally thereon.

13. A heat pump, refrigerator, drier or generator, comprising the thermoelectric module as claimed in claim 1 wound spirally onto a heat transfer medium line.
